(19) United States
(12) Patent Application Publication
(10) Pub. No.: US 2026/0247760 A1
(43) Pub. Date: Aug. 20, 2026

(54) Light-Emitting Module and Display Apparatus

(71) Applicants: Hefei BOE Ruisheng Technology Co., Ltd., Hefei, Anhui (CN); BOE TECHNOLOGY GROUP CO, LTD., Chaoyang District, Beijing (CN)

(72) Inventors: Yiding Sun, Beijing (CN); Amei Cheng, Beijing (CN); Kangli Wang, Beijing (CN); Haili Xu, Beijing (CN); Liang Gao, Beijing (CN); Qi Qi, Beijing (CN)

(21) Appl. No.: 18/992,078

(22) PCT Filed: Sep. 22, 2023
(86) PCT No.: PCT/CN2023/120890

§ 371 Date: Jan. 7, 2025

(51) Int. Cl. H10H 20/841; H10H 29/14; H10H 29/855

(52) U.S. Cl. CPC H10H 20/841; H10H 29/142; H10H 29/855

(57) ABSTRACT

A light-emitting module includes a substrate, a plurality of light-emitting devices, and a plurality of reflective patterns. The light-emitting devices are disposed on the substrate. The plurality of reflective patterns are disposed on a side of the light-emitting devices away from the substrate. Adjacent reflective patterns are provided with a gap therebetween. The reflective patterns are in one-to-one correspondence with the light-emitting devices, and an orthographic projection of a light-emitting device on the substrate is located within an orthographic projection of a reflective pattern on the substrate. The reflective pattern is provided with at least one through hole, and an orthographic projection of the through hole on the substrate is non-overlapping with the orthographic projection of the light-emitting device on the substrate.

### CROSS-REFERENCE TO RELATED APPLICATION

This application is the United States national phase of International Patent Application No. PCT/CN2023/120890 filed Sep. 22, 2023, the disclosure of which is hereby incorporated by reference in its entirety.

### BACKGROUND OF THE INVENTION

### Field of the Invention

The present disclosure relates to the field of display technologies, and in particular, to a light-emitting module and a display apparatus.

### Description of Related Art

The display apparatus usually has an image display function, and exemplarily, the display apparatus may include a liquid crystal display panel and a backlight source (Back Light), in which the backlight source is disposed at the back of the liquid crystal display panel to provide backlight therefor. The light-emitting effect of the backlight source will directly affect the display effect of the display apparatus.

### SUMMARY OF THE INVENTION

In an aspect, a light-emitting module is provided. The light-emitting module includes a substrate, a plurality of light-emitting devices, and a plurality of reflective patterns. The light-emitting devices are disposed on the substrate. The plurality of reflective patterns are disposed on a side of the light-emitting devices away from the substrate, where adjacent reflective patterns in the plurality of reflective patterns are provided with a gap therebetween; the reflective patterns are in one-to-one correspondence with the light-emitting devices, and an orthographic projection of a light-emitting device in the plurality of reflective patterns on the substrate is located within an orthographic projection of a reflective pattern in the plurality of reflective patterns on the substrate. The reflective pattern is provided with at least one through hole, and an orthographic projection of the at least one through hole on the substrate is non-overlapping with the orthographic projection of the light-emitting device on the substrate.

In some embodiments, the reflective pattern is provided with a plurality of through holes, and in the plurality of through holes, a number of through holes proximate to a center of the reflective pattern is less than a number of through holes away from the center of the reflective pattern.

In some embodiments, the reflective pattern is provided with a plurality of through holes of a same size.

In some embodiments, the reflective pattern is provided with a plurality of through holes, and in the plurality of through holes, a size of a through hole proximate to a center of the reflective pattern is less than a size of a through hole away from the center of the reflective pattern.

In some embodiments, the reflective pattern is provided with a plurality of through holes in multiple emission regions, through holes in each emission region having a same distance from a center of the reflective pattern, and the plurality of through holes are arranged in a circular array.

In some embodiments, the plurality of through holes are arranged in a staggered manner.

In some embodiments, a shape of the orthographic projection of the reflective pattern is a circle, and along any radial direction of the reflective pattern, multiple through holes in the plurality of through holes are arranged in sequence.

In some embodiments, the plurality of through holes are symmetrically distributed.

In some embodiments, a shape of the orthographic projection of the at least one through hole on the substrate is a circle or a polygon, and a size of the at least one through hole ranges from 0.1 mm to 0.2 mm.

In some embodiments, a minimum distance between the at least one through hole and an edge of the reflective pattern is 0.1 mm.

In some embodiments, a minimum distance between a through hole in the at least one through hole that is closest to a center of the reflective pattern and the center of the reflective pattern is 0.75 mm.

In some embodiments, the plurality of reflective patterns are arranged in an array, the plurality of reflective patterns include first reflective patterns and second reflective patterns, and along a direction of diagonal lines of the first reflective patterns, the first reflective patterns and the second reflective patterns are arranged in sequence.

A first reflective pattern in the first reflective patterns is provided with a plurality of through holes, and in the plurality of through holes, a number of through holes in a direction of a diagonal line of the first reflective pattern is greater than a number of through holes in a horizontal direction or a vertical direction; and/or a second reflective pattern in the second reflective patterns is provided with a plurality of through holes, and in the plurality of through holes, a number of through holes in the direction of a diagonal line of the first reflective pattern is greater than a number of through holes in the horizontal direction or the vertical direction.

In some embodiments, a shape of the reflective pattern is a circle or a polygon.

In some embodiments, a thickness of the reflective pattern ranges from 25 μm to 50 μm.

In some embodiments, a distance between a side of the reflective pattern proximate to the substrate and the light-emitting device ranges from 20 μm to 50 μm.

In some embodiments, the light-emitting module further includes a bottom reflective layer, disposed on a side of the substrate proximate to the plurality of reflective patterns.

In some embodiments, the light-emitting module further includes a protective layer, disposed on the plurality of light-emitting devices, where the plurality of reflective patterns are disposed on the protective layer.

In some embodiments, a refractive index of the protective layer is greater than a refractive index of the reflective pattern.

In some embodiments, a reflectivity of the reflective pattern ranges from 85% to 93%.

In another aspect, a display apparatus is provided. The display apparatus includes the light-emitting module according to any of the embodiments described above.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1A is a partial top view of a light-emitting board provided by the related art;

FIG. 1B is a cross-sectional view taken along line A1-A2 in FIG. 1A;

FIG. 1C is a schematic diagram showing the light output of a light-emitting board provided by the related art;

FIG. 2A is a partial top view of another light-emitting board provided by the related art;

FIG. 2B is a cross-sectional view taken along line B1-B2 in FIG. 2A;

FIG. 2C is a schematic diagram showing the light output of another light-emitting board provided by the related art;

FIG. 3 is a structural diagram of a display apparatus provided by embodiments of the present disclosure;

FIG. 4 is a structural diagram of another display apparatus provided by embodiments of the present disclosure;

FIG. 5 is a structural diagram of a light-emitting module provided by embodiments of the present disclosure;

FIG. 6 is a cross-sectional view taken along line C1-C2 in FIG. 5;

FIG. 7 is a structural diagram of a reflective pattern provided by embodiments of the present disclosure;

FIG. 8 is a schematic diagram showing the light output of a light-emitting region of a light-emitting module provided by embodiments of the present disclosure;

FIG. 9A is a structural diagram of another reflective pattern provided by embodiments of the present disclosure;

FIG. 9B is a cross-sectional view taken along line D1-D2 in FIG. 9A;

FIG. 10 is a structural diagram of yet another reflective pattern provided by embodiments of the present disclosure;

FIG. 11 is a structural diagram of still another reflective pattern provided by embodiments of the present disclosure;

FIG. 12 is a structural diagram of still yet another reflective pattern provided by embodiments of the present disclosure;

FIG. 13 is a structural diagram of still yet another reflective pattern provided by embodiments of the present disclosure;

FIG. 14 is a partially enlarged view of a light-emitting module corresponding to the E region of FIG. 8; and

FIG. 15 is a structural diagram of still yet another reflective pattern provided by embodiments of the present disclosure.

### DESCRIPTION OF THE INVENTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a/the plurality of” or “multiple” means two or more unless otherwise specified.

In the description of some embodiments, the terms such as “coupled” and “connected” and derivatives thereof may be used. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is, optionally, construed to mean “when” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context.

The use of “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or value beyond those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°, the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

With the advancement of liquid crystal display technology, more and more backlight sources use light-emitting devices. For example, micro light-emitting diodes or mini light-emitting diodes (Micro LEDs or Mini LEDs) are used in a light-emitting board of a light-emitting source.

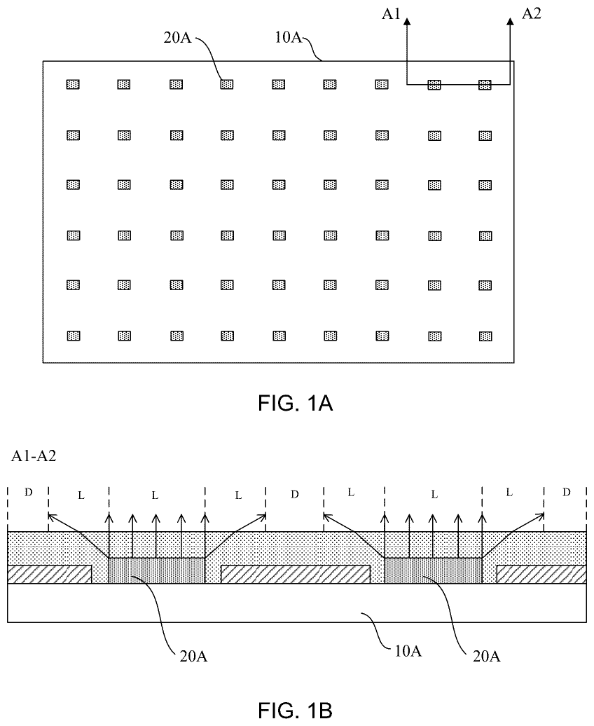

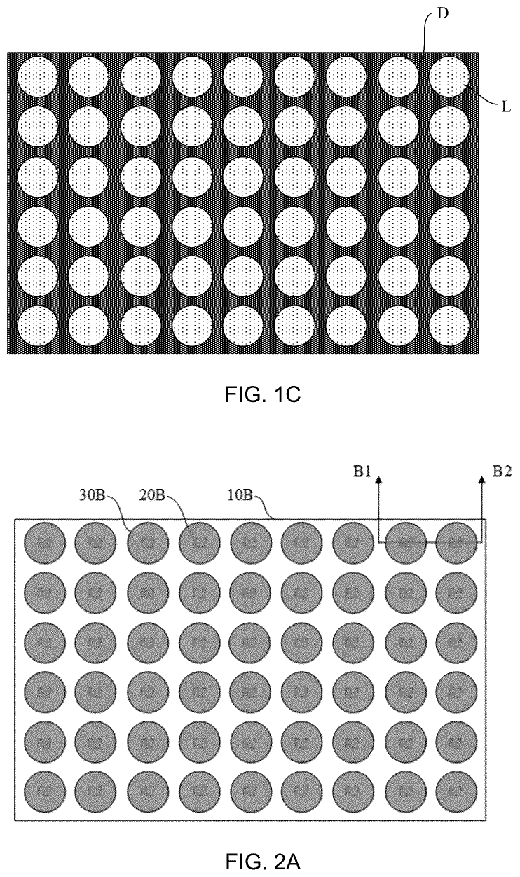

FIG. 1A is a partial top view of a light-emitting board provided by the related art. FIG. 1B is a cross-sectional view taken along line A1-A2 in FIG. 1A. FIG. 1C is a schematic diagram showing the light output of a light-emitting board provided by the related art.

Referring to FIG. 1A to FIG. 1C, the light-emitting board includes a substrate 10A and a plurality of light-emitting devices 20A, in which the light-emitting devices 20A are arranged in an array on the substrate 10A, and there is a gap (pitch) between adjacent light-emitting devices 20A. For the convenience of the following description, a region in the light-emitting board illuminated by a light-emitting device 20A is referred to as a bright region L, and a region in the light-emitting board not illuminated by the light-emitting device 20A is referred to as a dark region D. When the light-emitting device 20A emits light, light emitted in a vertical direction is directed outside the light-emitting board from the light-emitting side of the light-emitting device 20A, so that a region in the light-emitting board directly opposite to the light-emitting side of the light-emitting device 20A becomes a bright region L. In addition to the region directly opposite to the light-emitting side of the light-emitting device 20A, light is also emitted from a region surrounding the light-emitting side of the light-emitting device 20A (this portion of light is light emitted from the light-emitting side of the light-emitting device 20A in a non-vertical direction), so that a region in the light-emitting board directly opposite to the periphery of the light-emitting side of the light-emitting device 20A also becomes a bright region L. Referring to FIG. 1B and FIG. 1C, the farther away a region between adjacent light-emitting devices 20A is from the light-emitting devices 20A, the less light reaches, causing the brightness of the region between the light-emitting devices 20A to gradually decrease until the region becomes a dark region D of the light-emitting board, forming a light shadow. In a case where the light emitted by the light-emitting device 20A has a constant brightness, since the region of the light-emitting board illuminated by the light-emitting device 20A is limited, as the gap between the light-emitting devices 20A increases, a range (e.g., a region) of the dark region D between the light-emitting devices 20A increases, the problem of poor light shadow of the light-emitting board becomes more serious, resulting in worse brightness uniformity of the light-emitting board. In order to solve the above problem, a conventional approach is to reduce the gap between the light-emitting devices 20A to reduce the range of the dark region D, thereby improving the brightness uniformity of the light-emitting board. However, this approach will increase the number of light-emitting devices 20A, increasing the manufacturing cost of the light-emitting board.

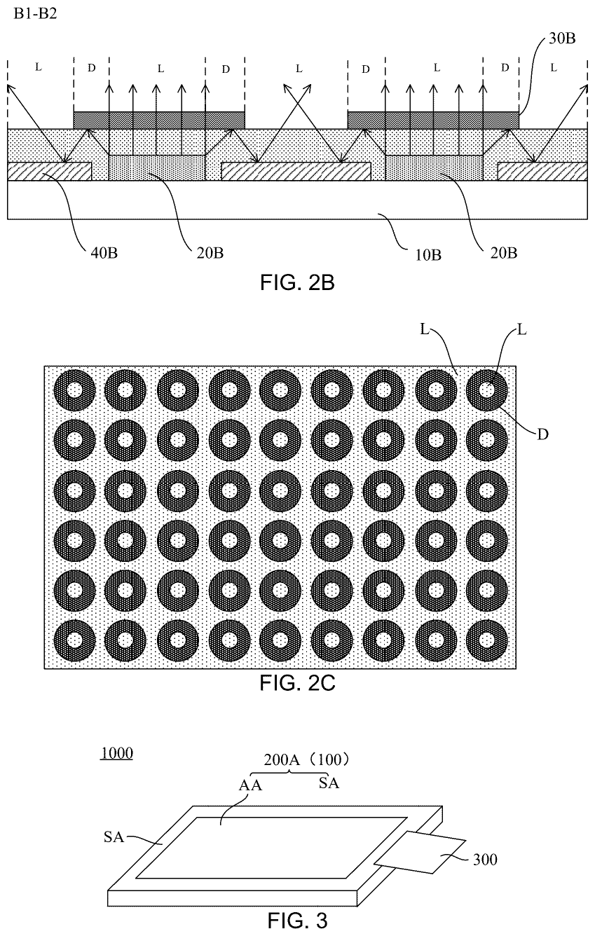

FIG. 2A is a partial top view of another light-emitting board provided by the related art. FIG. 2B is a cross-sectional view taken along line B1-B2 in FIG. 2A. FIG. 2C is a schematic diagram showing the light output of another light-emitting board provided by the related art.

In order to reduce the range of the dark region D, the dark region D will further be reduced by adding a reflective pattern 30B. Referring to FIG. 2A to FIG. 2C, a light-emitting board includes a substrate 10B, a plurality of light-emitting devices 20B, reflective patterns 30B, and a bottom reflective layer 40B disposed on the substrate 10B. There is a gap between light-emitting devices 20B, and a reflective pattern 30B is disposed on a light-emitting device 20B (on a side of the light-emitting device 20B away from the substrate 10B), covering the light-emitting device 20B. There is also a gap between reflective patterns 30B, where the gap between the reflective patterns 30B is smaller than the gap between the light-emitting devices 20B. When a light-emitting device 20B emits light, large-angle light emitted from a light-emitting side of the light-emitting device 20B irradiates the lower surface of a reflective pattern 30B (a side of the reflective pattern 30B proximate to the substrate 10B). As a result, the light is repeatedly reflected between the reflective pattern 30B and the bottom reflective layer 40B to the gap between the reflective patterns 30B, and is directed outside the light-emitting board from the gap between the reflective patterns 30B, so that a region corresponding to the gap between the reflective patterns 30B becomes a bright region L. That is to say, a portion of a region corresponding to the gap between the light-emitting devices 20B becomes a bright region, and the range of the dark region D between the light-emitting devices 20B is reduced. The light-emitting device 20B emits more light in the vertical direction from the light-emitting side of the light-emitting device 20B, and a portion of the light can be directly transmitted from the reflective pattern 30B, so that the light is emitted from a region in the reflective pattern 30B directly opposite to the light-emitting side of the light-emitting device 20B, and this region directly opposite to the light-emitting side of the light-emitting device 20B becomes a bright region L. Small-angle light emitted from the light-emitting device 20B is not sufficient to pass through the reflective pattern 30B, and is reflected repeatedly between the reflective pattern 30B and the bottom reflective layer 40B to the gap between the reflective patterns 30B, and is directed outside the light-emitting board from the gap between the reflective patterns 30B. In this way, the amount of light emitted from the gap between the reflective patterns 30B is increased, and the brightness of the bright region L corresponding to the gap between the reflective patterns 30B increases. However, there is no region in the reflective pattern 30B that is directly opposite to the light-emitting side of the light-emitting device 20B, so the light emitted from the light-emitting device 20B is difficult to pass through this region directly, and can only be reflected in this region. As a result, the region in the reflective pattern 30B which is not directly opposite to the light-emitting side of the light-emitting device 20B does not emit light, becoming a dark region D. Compared with the structure of the light-emitting board illustrated in FIG. 1A, in the light-emitting board shown in FIG. 2A, although a portion of the region corresponding to the gap between the light-emitting devices has become a bright region L, a portion of the region directly opposite to the reflective pattern 30B is still a dark region D, and a problem of poor light shadow still exists, and the brightness uniformity of the light-emitting board is still poor.

In order to solve the above problems, some embodiments of the present disclosure provide a display apparatus 1000. The display apparatus 1000 is an electronic device having an image (including: a still image or a moving image, where the moving image may be a video) display function. For example, the display apparatus may be any one of a displayer, a television, a billboard, a digital photo frame, a laser printer with a display function, a telephone, a mobile phone, a personal digital assistant (PDA), a digital camera, a portable camcorder, a viewfinder, a navigator, a large-area wall, a home appliance, an information query device (e.g., business query device for e-government, banks, hospitals, electric power, etc.), a monitor, an electronic picture screen, a virtual reality (VR) display apparatus, an augmented reality (AR) display apparatus, and a vehicle-mounted display, but not limited to any of these.

FIG. 3 is a structural diagram of a display apparatus provided by embodiments of the present disclosure.

In some embodiments, referring to FIG. 3, the display apparatus 1000 may include a display panel 200A, which may be, for example, a self-luminous display panel. The display panel 200A has a display region AA and a peripheral region SA, in which the display region AA is a region on the display panel 200A for displaying images, while the peripheral region SA is a region on the display panel 200A other than the display region AA. The peripheral region SA may be located on at least one side (e.g., one side, or multiple sides) of the display region AA. For example, the peripheral region SA may be disposed around all sides of the display region AA.

The display panel 200A may be a micro/mini light-emitting diode (Micro LED or Mini LED) display panel. The display panel 200A may include a light-emitting module 100, in which the light-emitting module 100 has a light-emitting region and a non-light-emitting region. The light-emitting region is a region in the light-emitting module 100 that is defined by the display region AA of the display panel 200A, and the light-emitting region of the light-emitting module 100 has the same shape and size as the display region AA of the display panel 200A. The non-light-emitting region is a region in the light-emitting module 100 other than the light-emitting region.

The display apparatus 1000 may further include at least one (e.g., one or more) of a frame, a circuit board 300, etc. Here, the circuit board 300 may be a flexible printed circuit (FPC) or a printed circuit board (PCB). The circuit board 300 may be coupled to the display panel 200A, and configured to transmit electrical signals to the display panel 200A. In addition, both the display panel 200A and the circuit board 300 may be mounted into a space enclosed by the frame.

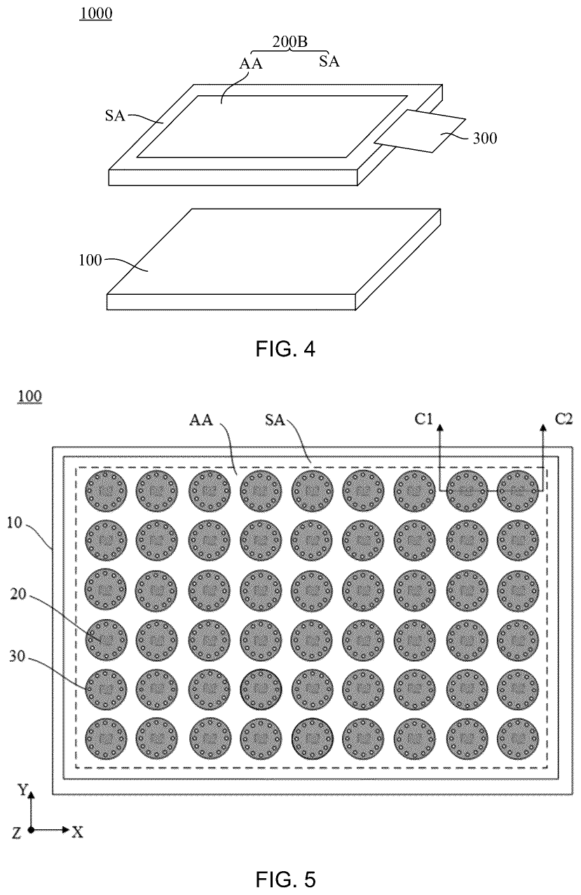

FIG. 4 is a structural diagram of another display apparatus provided by embodiments of the present disclosure.

In some other embodiments, referring to FIG. 4, the display apparatus 1000 may include a display panel 200B and a light-emitting module 100. The display panel 200B may be a liquid crystal display panel. The display panel 200B has a display region AA and a peripheral region SA. The light-emitting module 100 is disposed on the backside of the display panel 200B and is configured to provide a backlight to the display panel 200B. The light-emitting module 100 has a light-emitting region and a non-light-emitting region. The light-emitting region is a region in the light-emitting module 100 that is defined by the display region AA of the display panel 200B, and the light-emitting region of the light-emitting module 100 has the same shape and size as the display region AA of the display panel 200B. The non-light-emitting region is a region in the light-emitting module 100 other than the light-emitting region.

The display apparatus 1000 may further include at least one of a frame, a circuit board 300, etc. The specific structure can be referred to in the relevant description for the display apparatus 1000 shown in FIG. 3 and will not be repeated herein.

To facilitate the following description, an XYZ coordinate system is established. Both the first direction X and the second direction Y are parallel to a plane in which the light-emitting module 100 is located, and, both cross. For example, the first direction X and the second direction Y are perpendicular to each other. The third direction Z is a thickness direction of the light-emitting module 100, and the third direction Z is perpendicular to the XY plane.

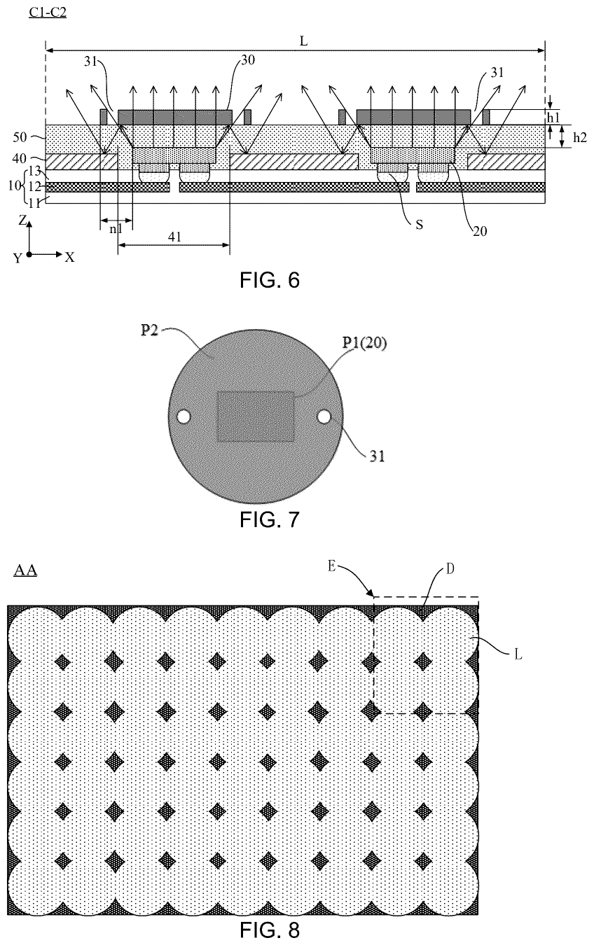

FIG. 5 is a structural diagram of a light-emitting module provided by embodiments of the present disclosure. FIG. 6 is a cross-sectional view taken along line C1-C2 in FIG. 5.

Referring to FIG. 5, the light-emitting module 100 has a light-emitting region AA. The light-emitting module 100 may further have a non-light-emitting region SA. The non-light-emitting region SA may be located on at least one side (e.g., one side, or four sides, including upper and lower sides and left and right sides) of the light-emitting region AA. For ease of description herein, the reference symbol “AA” indicates the light-emitting region as well as the display region, and the reference symbol “SA” indicates the non-light-emitting region as well as the peripheral region. The light-emitting module 100 includes a substrate 10, a plurality of light-emitting devices 20, and a plurality of reflective patterns 30.

The substrate 10 includes a base substrate, and the base substrate acts as a support for other structures in the light-emitting module 100. The base substrate may be set according to practical needs. For example, the base substrate may be a rigid substrate. The material of the rigid substrate may be glass or polymethyl methacrylate (PMMA). Alternatively, the base substrate may be a flexible substrate. The material of the flexible substrate may be polyethylene terephthalate (PET), polyethylene naphthalate two formic acid glycol ester (PEN), ultra-thin glass, or polyimide (PI).

The substrate 10 may further include a circuit layer disposed on the base substrate. The circuit layer is coupled to the plurality of light-emitting devices 20, and is configured to provide an electrical signal to each light-emitting device 20, enabling the light-emitting device 20 to emit light of a corresponding brightness.

For example, referring to FIG. 6, the substrate 10 includes a first insulating layer 11, a circuit layer 12, and a second insulating layer 13 stacked in sequence. The first insulating layer 11 and the second insulating layer 13 are used to isolate the circuit layer 12 from short circuits and interference. The material of each of the first insulating layer 11 and the second insulating layer 13 may be one or a combination of more of glass, PMMA, PET, PEN, or PI, and the materials of the first insulating layer 11 and the second insulating layer 13 may be the same or different, and the embodiments of the present disclosure are not limited thereto. The circuit layer 12 is used to provide a conductive path required by the circuit board 300. The material of the circuit layer 12 may be a conductive material, such as copper foil. The circuit layer 12 is provided between the first insulating layer 11 and the second insulating layer 13. The second insulating layer 13 is provided with first openings, and the first openings extend through the second insulating layer 13, exposing a portion of the circuit layer 12. The light-emitting devices 20 are connected to the circuit layer 12 through the first openings. For example, pins of a light-emitting device 20 are directly connected to the circuit layer 12; as another example, the circuit layer 12 is provided with solders S, and the pins of the light-emitting device 20 are connected to the circuit layer 12 through a solder S. The circuit layer 12 may be connected to the circuit board 300, thereby realizing that the light-emitting module 100 is connected to the circuit board 300.

The light-emitting device 20 is an electronic device capable of emitting light. The plurality of light-emitting devices 20 are disposed on the substrate 10 and located in the light-emitting region AA. The light-emitting device 20 may be an inorganic light-emitting diode (LED), for example, may be any one of a Mini LED device and a Micro LED device. The embodiments of the present disclosure do not limit the light-emitting device 20, which means that the light-emitting device 20 may be a light-emitting device of any one of other types.

Although a limited number of light-emitting devices 20 are shown in FIG. 5, the number of the light-emitting devices 20 in the embodiments of the present disclosure is not limited. Gaps are provided between the light-emitting devices 20. In some embodiments, the plurality of light-emitting devices 20 may be arranged in an array, for example, arranged in N rows and M columns, where N is an integer greater than 0, and M is an integer greater than 0. For example, N is greater than or equal to 2, and M is greater than or equal to 2(N≥2, M≥2). In some other embodiments, the plurality of light-emitting devices 20 may be arranged in any one of other manners, such as in a pattern to be displayed, and is not limited to a matrix arrangement.

FIG. 7 is a structural diagram of a reflective pattern provided by embodiments of the present disclosure. FIG. 8 is a schematic diagram showing the light output of a light-emitting region of a light-emitting module provided by embodiments of the present disclosure.

Continuing with FIG. 6, the reflective pattern 30 is located on a side of the light-emitting device 20 away from the substrate 10, in which the upper surface of the reflective pattern 30 is a surface of the reflective pattern 30 at a side thereof away from the substrate 10, and the lower surface of the reflective pattern 30 is a surface of the reflective pattern 30 at a side thereof proximate to the substrate 10. The plurality of reflective patterns 30 correspond one-to-one with the plurality of light-emitting devices 20, i.e., one light-emitting device 20 corresponds to one reflective pattern 30. The arrangement of the plurality of reflective patterns 30 is the same as the arrangement of the plurality of light-emitting devices 20. For example, the plurality of light-emitting devices 20 are arranged in a rectangular array, and the plurality of reflective patterns are also arranged in a rectangular array. The upper surface of the reflective pattern 30 and the lower surface of the reflective pattern 30 may be parallel to each other, that is, the reflective pattern has the same thickness at various positions. For example, the upper surface of the reflective pattern 30 is a plane, and the lower surface of the reflective pattern 30 is also a plane; as another example, the upper surface of the reflective pattern 30 is a curved surface, and the lower surface of the reflective pattern 30 is a curved surface parallel to the curved surface. An orthographic projection of the reflective pattern 30 on the substrate 10 covers an orthographic projection of the light-emitting device 20 on the substrate 10, that is, the orthographic projection of the light-emitting device 20 on the substrate 10 is located within a contour of the orthographic projection of the reflective pattern 30 on the substrate. Specifically, referring to FIG. 7, the reflective pattern 30 includes a first sub-pattern P1 and a second sub-pattern P2. Here, an orthographic projection of the first sub-pattern P1 on the substrate 10 coincides with the orthographic projection of the light-emitting device 20 on the substrate 10, the first sub-pattern P1 is a region corresponding to an orthographic projection of the light-emitting device 20 on the reflective pattern 30, and an edge of the first sub-pattern P1 is opposite to an edge of the light-emitting device 20; and an orthographic projection of the second sub-pattern P2 on the substrate 10 is non-overlapping with the orthographic projection of the light-emitting device 20 on the substrate 10. In this way, the light directly emitted from the light-emitting device 20 perpendicular to the lower surface of the first sub-pattern P1 can directly pass through the first sub-pattern P1 and be emitted out of the light-emitting module 100; and the light directly emitted from the light-emitting device 20 in other directions will be reflected multiple times on the lower surface of the reflective pattern 30. A region corresponding to each first sub-pattern P1 in the light-emitting module 100 becomes a bright region L.

There is a gap between adjacent reflective patterns 30, which can be understood that there is a gap between second sub-patterns P2 of the adjacent reflective patterns 30. There is also a gap between the light-emitting devices 20. Since the projection of the reflective pattern 30 covers the projection of the light-emitting device 20, the reflective pattern 30 may cover a portion of the gap between the light-emitting devices 20, and thus the gap between the reflective patterns 30 is smaller than the gap between the light-emitting devices 20.

The reflective pattern 30 is provided with at least one (e.g., one or more) through hole 31. Specifically, the through hole 31 extends through the upper and lower surfaces of the reflective pattern 30. An orthographic projection of the through hole 31 on the substrate 10 is non-overlapping with the orthographic projection of the light-emitting device 20 on the substrate 10. Specifically, the through hole 31 is disposed in the second sub-pattern P2 of the reflective pattern 30. Some of the light emitted by the light-emitting device 20 is reflected by the reflective pattern 30 and finally irradiates the lower surface of the second sub-pattern P2. A portion of the light directly enters the through hole 31, and is emitted from the through hole 31 to the outside of the light-emitting module 100. In this way, a region corresponding to the second sub-pattern P2 of the reflective pattern 30 emits light to become a bright region L, so that a region in the light-emitting module 100 that was originally a dark region D becomes the bright region L, reducing the range of the dark region D in the light-emitting module 100; the other portion of the light does not enter the through hole 31, and is reflected to the gap between adjacent reflective patterns 30 under the reflection effect of the lower surface of the second sub-pattern P2, and is emitted from the outside of the light-emitting module 100 from the gap between the reflective patterns 30. In this way, a region corresponding to the gap between the reflective patterns 30 becomes a bright region L, that is, a portion of the region corresponding to the gap between the light-emitting devices 20 becomes the bright region L, reducing the range of the dark region D in the corresponding region between the light-emitting devices 20 in the light-emitting module 100. Light is emitted from the region corresponding to the reflective pattern 30 in the light-emitting module 100 (the region corresponding to the first sub-pattern P1 and the second sub-pattern P2), and light is also emitted from the gap between the light-emitting devices 20, so that the range of the dark region D in the light-emitting module 100 is reduced, the brightness uniformity of the light-emitting module 100 is improved, and the display effect of the display apparatus is improved.

The larger the gap between the light-emitting devices 20 is, if the size of the reflective pattern 30 remains unchanged, then light will still be emitted from a region proximate to the reflective pattern 30 in the gap between the light-emitting devices 20, but a distance from a region away from the reflective pattern 30 is large, causing a region away from the reflective pattern 30 in the gap between the light-emitting devices 20 to become a dark region D again. Therefore, the larger the gap between the light-emitting devices 20 is, the larger the size of the reflective pattern 30 is. Specifically, the larger the gap between the light-emitting devices 20 is, the larger size of the second sub-pattern P2 is. For example, referring to FIG. 6, the larger the gap between the light-emitting devices 20 is, the larger a distance from an edge of the first sub-pattern P1 to an outer edge of the second sub-pattern P2 is, i.e., a distance n1 from the edge of the light-emitting device 20 to the outer edge of the second sub-pattern P2 is larger. A portion of the light emitted by the light-emitting device 20 is emitted from the gap of the reflective patterns 30 under the reflection effect of the second sub-pattern P2; the other portion of the light is emitted through the through hole 31 of the second sub-pattern P2. In this way, the light is always emitted from the region proximate to the second sub-pattern P2 and the region away from the second sub-pattern P2 in the gap of the light-emitting devices 20, thereby reducing the range of the dark region D formed in the gap corresponding to the light-emitting devices 20.

The reflective pattern 30 may be formed by screen printing technology, or by a film deposition process such as chemical vapor deposition (CVD), physical vapor deposition (PVD), or atomic layer deposition (ALD). The reflective pattern 30 may be made of a material with low light transmittance and high reflectivity. The reflectivity of the reflective pattern 30 ranges from 85% to 93%, such as 85%, 88%, 90%, or 93%. The material of the reflective pattern 30 may be white ink or white silica gel. If the reflectivity is too high, the light emitted by the light-emitting device 20 is almost completely reflected on the lower surface of the reflective pattern 30, resulting in no light passing through the orthographic projection region (the first sub-pattern P1) of the light-emitting device 20 on the reflective pattern, so that almost no light is emitted from the region directly opposite to the first sub-pattern P1 in the light-emitting module 100, forming a dark region D. If the reflectivity is too low, the light emitted by the light-emitting device 20 is difficult to be emitted from the region between adjacent light-emitting devices 20 after multiple reflections on the lower surface of the reflective pattern 30, causing the region corresponding to the gap between the light-emitting devices 20 in the light-emitting module 100 to become a dark region D, which is not conducive to improving the brightness uniformity of the light-emitting module 100. The reflective pattern 30 and the light-emitting device 20 corresponding thereto may be coaxially arranged. Specifically, a line connecting the geometric center of the reflective pattern 30 and the geometric center of the light-emitting device 20 is perpendicular to a plane where the substrate 10 is located.

A shape of the orthographic projection of reflective pattern 30 on the substrate 10 may be circular or polygonal. The shape of the reflective pattern 30 may be similar to a shape of the orthographic projection of the light-emitting device 20 on the substrate 10. For example, the orthographic projection of the light-emitting device 20 on the substrate 10 is a rectangle, and the reflective pattern 30 is also in the shape of a rectangle. In this case, the long side of the orthographic projection of the reflective pattern 30 on the substrate 10 is parallel to the long side of the orthographic projection of the light-emitting device 20 on the substrate 10, and the short side of the orthographic projection of the reflective pattern 30 on the substrate 10 is parallel to the short side of the orthographic projection of the light-emitting device 20 on the substrate 10; and the diagonal line of the orthographic projection of the reflective pattern 30 on the substrate 10 may coincide with the diagonal line of the orthographic projection of the light-emitting device 20 on the substrate 10.

In some other implementations, the shape of the orthographic projection of the reflective pattern 30 on the substrate 10 may be different from the shape of the orthographic projection of the light-emitting device 20 on the substrate 10. For example, the orthographic projection of the light-emitting device 20 on the substrate 10 is in the shape of a circle, and the orthographic projection of the reflective pattern 30 on the substrate 10 is in the shape of a polygon.

In the embodiments of the present disclosure, a portion of the light emitted by the light-emitting device 20 is emitted through the through hole 31 of the reflective pattern 30, and the reflective pattern 30 plays a role in uniformizing the light. Therefore, under the condition of the same display area, using the light-emitting module 100 of the embodiments of the present disclosure may reduce the number of the light-emitting devices 20 and save costs.

In order to achieve the display function, a conventional display apparatus includes a light-emitting module and an optical film group formed by at least a diffusion sheet, a prism sheet, a light uniformizing film, etc., in which the light-emitting module plays a role in emitting light, and the diffusion sheet in the optical film group plays a role in uniformizing light. In some examples, in a case where the light-emitting devices of the light-emitting module emits monochromatic light (such as blue light), a color conversion film (such as a quantum dot film or a phosphor film), which converts the monochromatic light into complex color light, is included.

In the light-emitting module 100 of the embodiments of the present disclosure, the reflective pattern 30 has the function of uniformizing light, and the light-emitting module 100, a prism sheet, and a light uniformizing film/color conversion film in the display apparatus 1000 can realize the display function. The stacked structure, which is composed of the prism sheet, the light uniformizing film and the color conversion film, is in direct contact with the reflective patterns 30 of the light-emitting module 100. Without the need for the diffusion sheet, the thickness of the stacked structure is reduced, thereby reducing the thickness of the display apparatus, especially for small and medium-sized (e.g., 20 inches or less) display apparatuses 1000, which is conducive to achieving lightweight.

In some embodiments, the light-emitting module further includes a bottom reflective layer 40. The bottom reflective layer 40 is disposed on a side of the substrate 10 proximate to the plurality of reflective patterns 30, specifically, the bottom reflective layer 40 is located below the reflective patterns 30. For example, continuing to refer to FIG. 6, the bottom reflective layer 40 includes a plurality of second openings 41, in which a projection of a second opening 41 on the substrate 10 is at a certain distance from a projection of a light-emitting device 20 on the substrate 10. When forming the light-emitting module 100, an initial bottom reflective layer is first formed, and the initial bottom reflective layer is etched to form the second openings 41, so as to expose a portion of the substrate 10. The light-emitting device 20 is disposed in the second opening 41 and connected to the substrate 10. In some examples, the projection of the through hole 31 on the substrate 10 is non-overlapping with the second opening 41, that is, a projection of the substantial portion of the reflective pattern 30 on the substrate 10 covers the second opening 41. In this way, the light emitted from the edge of the light-emitting device 20 will not directly exit through the through hole 31, which will not cause excessive brightness in the portion of the second sub-pattern P2 proximate to the first sub-pattern P1, thereby avoiding a clear boundary between the brightness of this portion and the brightness of the portion of the second sub-pattern P2 proximate to the outer edge and away from the first sub-pattern P1, which is beneficial for maintaining the brightness uniformity of the light-emitting module 100.

As another example, there is no gap between the projection of the bottom reflective layer 40 on the substrate 10 and the projection of the light-emitting device 20 on the substrate 10. When forming the light-emitting module 100, the plurality of light-emitting devices 20 are firstly arranged on the substrate 10, the light-emitting devices 20 are connected to the substrate 10, and then the bottom reflective layer 40 is formed between the light-emitting devices 20. In the embodiments of the present disclosure, the bottom reflective layer 40 is disposed below the reflective patterns 30. The non-vertical light emitted from the light-emitting device 20 is emitted to the lower surface of the reflective pattern 30. A portion of the light is directly emitted from the through hole 31, and the other portion of the light is reflected by the reflective pattern 30 and irradiated onto the bottom reflective layer 40, and then reflected on the bottom reflective layer 40, so that the light is repeatedly reflected between the reflective pattern 30 and the bottom reflective layer 40 until it is emitted from the through hole 31 or the gap between the reflective patterns 30 to the outside of the light-emitting module 100. Repeated reflection can increase an optical path of the light emitted by the light-emitting device 20, and can also increase the amount of light emitted from the through hole 31 or the gap of the reflective patterns 30, thereby increasing the brightness of the through hole 31 and the gap of the reflective patterns 30 of the light-emitting module 100, thereby improving the brightness uniformity of the light-emitting module 100 and enhancing the display effect. In some embodiments, referring to FIG. 6, the light-emitting module 100 further includes a protective layer 50. The protective layer 50 is disposed on the plurality of light-emitting devices 20 to cover the light-emitting devices 20, thereby preventing water and oxygen from corroding the light-emitting devices 20, and thus helping to extend the life span of the light-emitting module 100. The plurality of reflective patterns 30 are disposed on the protective layer 50, and a light mixing distance is left between the light-emitting devices 20 and the reflective patterns 30. The light emitted by the light-emitting devices 20 is fully mixed in the protective layer 50, achieving the effect of uniformizing light. The thicker the protective layer 50 is, the larger the light mixing distance is, the more fully the light emitted by the light-emitting devices 20 is mixed, the more evenly the light is emitted between the gap of the light-emitting devices 20, and the more evenly the brightness of the region corresponding to the gap of the light-emitting devices 20 is. In this case, if the size of the reflective pattern 30 is larger, the larger the gap between the light-emitting devices 20 is covered, and the light in the covered region in the gap of the light-emitting devices 20 needs to pass through the reflective pattern 30 in order to be emitted out of the light-emitting module 100., making the brightness between the gaps between the light-emitting devices 20 uneven. Therefore, in order to improve the brightness uniformity between the gaps of the light-emitting devices 20, the thicker the protective layer 50 is, the smaller the size of the reflective pattern 30 is.

The upper surface of the protective layer 50 (a surface of the protective layer 50 at a side thereof away from the substrate 10) may be a flat surface, a curved surface, or any one of other uneven surfaces. The lower surface of the reflective pattern 30 is in contact with and fits a corresponding region of the upper surface of the protective layer 50. That is, the shapes of the lower surface of the reflective pattern 30 and the corresponding region of the upper surface of the protective layer 50 match each other. For example, the corresponding region of the upper surface of the protective layer 50 is a flat surface, and the lower surface of the reflective pattern 30 is also a flat surface; as another example, the corresponding region of the upper surface of the protective layer 50 is a curved surface, and the lower surface of the reflective pattern 30 is a curved surface that fits therewith.

In order to improve the light transmission rate, the material of the protective layer 50 is a transparent material, such as one or a combination of more of SiOₓ, SiNₓ, SiOₓN_{y}, AlN, etc., or may also include any one of other suitable materials. The light emitted from the light-emitting devices 20 passes through the transparent protective layer 50, and the light is fully mixed within the protective layer 50 and then emitted onto the lower surface of the reflective patterns 30, which in turn emits the light-emitting module 100.

In some embodiments, the refractive index of the protective layer 50 is greater than the refractive index of the reflective pattern 30. The light emitted from the light-emitting device 20 is directed to the reflective pattern 30 through the protective layer 50. That is, the light enters the reflective pattern 30 with the low refractive index from the protective layer 50 with the high refractive index, and the total reflection phenomenon occurs when an incident angle of the light directed to the reflective pattern 30 is greater than the critical angle. In this way, large-angle light (the light with an incident angle greater than the critical angle for total reflection) is totally reflected at an interface between the protective layer 50 and the reflective pattern 30. The large-angle light is repeatedly reflected between the reflective pattern 30 and the bottom reflective layer 40, and is emitted from the through hole 31 or the gap of the reflective patterns 30 to the outside of the light-emitting module 100, thereby reducing the amount of large-angle light emitted from the region directly opposite to the light-emitting device 20, thereby reducing the difference in luminous brightness between the first sub-pattern P1 and the second sub-pattern P2, thereby improving the brightness uniformity of the light-emitting module 100 and enhancing the display effect.

In some embodiments, a thickness of the reflective pattern 30 is a first height h1, and the first height h1 ranges from 25 μm to 50 μm, such as 25 μm, 30 μm, 35 μm, 40 μm, 45 μm, or 50 μm. The thickness of the reflective pattern 30 cannot be too high, otherwise, the transmittance of the light emitted by the light-emitting device 20 through the reflective pattern 30 is reduced, and the light emitted from the region of the reflective pattern 30 directly opposite to the light-emitting device 20 is reduced, resulting in an increase in the brightness difference of the reflective pattern 30. The thickness of the reflective pattern 30 also cannot be too low, otherwise, the light emitted by the light-emitting device 20 directly passes through the reflective pattern 30, and the reflective pattern 30 does not play a reflective role, resulting in the gap region of the reflective pattern 30 still being a dark region D.

In some embodiments, a distance between the lower surface of the reflective pattern 30 and the light-emitting device 20 is a second height h2, and the second height h2 ranges from 20 μm to 50 μm, such as 20 μm, 25 μm, 30 μm, 40 μm, or 50 μm. The light emitted by the light-emitting device 20 is fully mixed within the range of the second height h2, achieving the effect of uniformizing light.

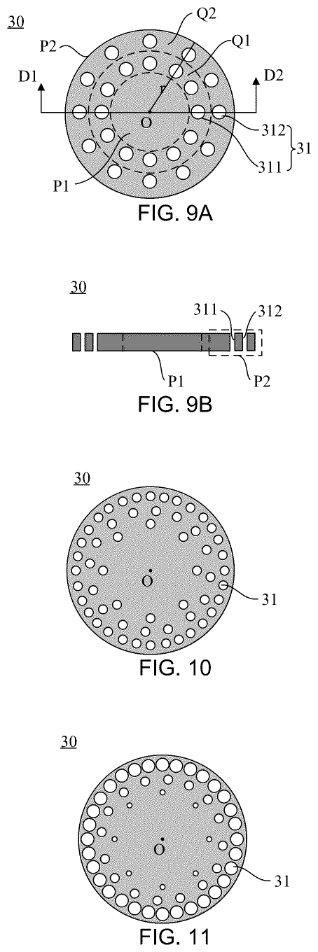

FIG. 9A is a structural diagram of another reflective pattern provided by embodiments of the present disclosure. FIG. 9B is a cross-sectional view taken along line D1-D2 in FIG. 9A.

In some embodiments, referring to FIG. 9A and FIG. 9B, the second sub-pattern P2 is provided with multiple annular emission regions, and each emission region is provided with at least one through hole (e.g., one or more) 31. Each annular emission region has the same distance from the center of the reflective pattern 30. That is, at least one through hole 31 is disposed in each of regions of the second sub-pattern P2 that have different distances from the center O of the reflective pattern 30. The geometric center of the reflective pattern 30 is located in the region where the first sub-pattern P1 is located. For example, the geometric center of the reflective pattern 30 may be coaxial with the geometric center of the light-emitting device 20. For example, a plurality of through holes 31 include first through holes 311 and second through holes 312, the multiple annular emission regions include a first emission region Q1 and a second emission region Q2, the first through holes 311 are located in the first emission region Q1, and the second through holes 312 are located in the second emission region Q2, where the first through holes 311 are closer to the center O of the reflective pattern 30 than the second through holes 312. The light emitted by the light-emitting device 20 is emitted outside the light-emitting module 100 through the first through holes 311 and the second through holes 312. That is, from the center O to the edge of the reflective pattern 30, the light can be emitted from the first emission region Q1 and the second emission region Q2 of the second sub-pattern P2 in sequence. Light is emitted from each annular emission region, which improves the brightness uniformity of the second sub-pattern P2, and the amount of light emitted from the second sub-pattern P2 increases, so that the brightness of the region of the light-emitting module 100 corresponding to the second sub-pattern P2 is increased, and the brightness difference at the gap between the second sub-pattern P2 and the reflective pattern 30 is reduced, further improving the brightness uniformity of the light-emitting module 100, thereby improving the display effect of the display apparatus.

In some embodiments, continuing to refer to FIG. 9A, the plurality of through holes 31 are of the same size, so the plurality of through holes 31 may be formed at the same time without adjusting the size of the etching in the fabrication process, which is conducive to simplifying the fabrication process and improving the fabrication efficiency.

FIG. 10 is a structural diagram of yet another reflective pattern provided by embodiments of the present disclosure.

In some embodiments, the number of through holes 31 proximate to the center O of the reflective pattern 30 is less than the number of through holes 31 away from the center O of the reflective pattern 30. Specifically, the number of through holes 31 in an emission region proximate to the center O of the reflective pattern 30 is less than the number of through holes 31 in an emission region away from the center O of the reflective pattern 30. For example, referring to FIG. 10, the closer to the center O of the reflective pattern 30, the smaller the density of the through holes 31; and the farther away from the center O of the reflective pattern 30, the larger the number of the through holes 31. In general, the light emission angle of the light-emitting device 20 is within 120°, and most of the light is concentrated in a very small three-dimensional angle. The closer to the center of the light-emitting device 20, the denser the light is and the higher the brightness is; and the further away from the center of the light-emitting device 20, the sparser the light is and the lower the brightness is. In this way, the closer to the center O of the reflective pattern 30, the larger the amount of light emitted by the light-emitting device 20 to the reflective pattern 30 is; and the farther away from the center of the reflective pattern 30, the smaller the amount of light emitted by the light-emitting device 20 to the reflective pattern 30 is. If the reflective pattern 30 is provided with no through hole 31, the closer to the center O of the reflective pattern 30, the more light is transmitted through the reflective pattern 30, and the brightness of the corresponding region is higher, resulting in poor brightness uniformity of the light emitted from the region where the same reflective pattern 30 is located. Since the number of through holes 31 increases as the distance from the center O of the reflective pattern 30 increases, the more light is emitted from the light-emitting module 100 through the through holes 31 as the distance from the center O of the reflective pattern 30 increases, and the region corresponding to the reflective pattern 30 becomes brighter, so that the light emitted from the light-emitting device 20 is redistributed, and the emitted luminous flux is uniformized on the same reflective pattern 30, thereby improving the brightness uniformity of the same reflective pattern 30, and further improving the uniformity of the light emitted from the light-emitting module 100, and a planar light source with a relatively high uniformity may be formed.

FIG. 11 is a structural diagram of still another reflective pattern provided by embodiments of the present disclosure.

In some embodiments, referring to FIG. 11, the size of a through hole 31 proximate to the center of the reflective pattern 30 is less than the size of a through hole 31 away from the center of the reflective pattern 30. Specifically, the size of a through hole 31 in an emission region proximate to the center O of the reflective pattern 30 is less than the size of a through hole 31 in an emission region away from the center O of the reflective pattern 30. For example, referring to FIG. 11, the closer to the center O of the reflective pattern 30, the smaller the size of the through hole 31; the farther away from the center O of the reflective pattern 30, the larger the size of the through hole 31. The closer to the center of the light-emitting device 20, the denser the light is and the higher the brightness is, while the farther away from the center of the light-emitting device 20, the sparser the light is and the lower the brightness is. Therefore, the closer to the center O of the reflective pattern 30, the larger the amount of light emitted by the light-emitting device 20 to the reflective pattern 30 is; and the farther away from the center of the reflective pattern 30, the smaller the amount of light emitted by the light-emitting device 20 to the reflective pattern 30 is. In this way, the closer to the center O of the reflective pattern 30, the larger the amount of light emitted by the light-emitting device 20 to the reflective pattern 30 is; and the farther away from the center O of the reflective pattern 30, the smaller the amount of light emitted by the light-emitting device 20 to the reflective pattern 30 is. The closer to the center O of the reflective pattern 30, the less light the light-emitting device 20 emits from the through hole 31; and the farther away from the center O of the reflective pattern 30, the more light the light-emitting device 20 emits from the through hole 31. In this way, although the brightness of the light emitted by the light-emitting device 20 becomes smaller and smaller along a radial direction of the reflective pattern 30, the amount of the light emitted by the light-emitting device 20 becomes more and more, so that the emitted light is redistributed, and the emitted light flux is uniformized on the same reflective pattern 30, thereby improving the brightness uniformity of the same reflective pattern 30, and then improving the uniformity of the light emitted by the light-emitting module 100, and a planar light source with a relatively high uniformity may be formed.

In some embodiments, continuing to refer to FIG. 11, the plurality of through holes 31 are in multiple emission regions, through holes 31 in each emission region having a same distance from a center of the reflective pattern 30, and the plurality of through holes 31 are arranged in a circular array, so that the light emitted by the light-emitting device 20 is more evenly distributed on the reflective pattern 30.

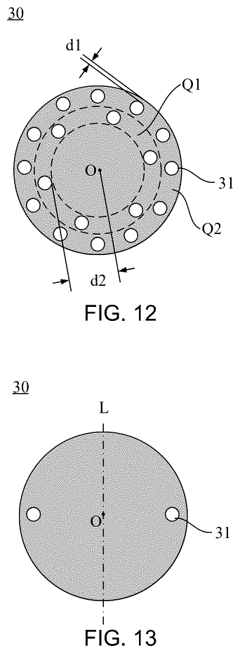

FIG. 12 is a structural diagram of still yet another reflective pattern provided by embodiments of the present disclosure.

In some embodiments, referring to FIG. 12, the plurality of through holes 31 are arranged in a staggered manner. Specifically, along a radial direction of the reflective pattern 30, the through holes 31 located in the first emission region Q1 and the through holes 31 located in the second emission region Q2 are arranged in a staggered manner, to reduce a distance between the through holes 31 and increase the number of the through holes 31, which further increases the amount of light emitted from the through holes 31, thereby improving the brightness uniformity of the light-emitting module 100.

In some embodiments, continuing to refer to FIG. 9A, along any radial direction of the reflective pattern 30, multiple through holes 31 are arranged in sequence. Specifically, from the center O of the reflective pattern 30 to the edge of the reflective pattern 30, multiple through holes 31 are sequentially arranged on the same radius “r”. The through holes 31 are arranged in sequence for ease of fabrication.

FIG. 13 is a structural diagram of still yet another reflective pattern provided by embodiments of the present disclosure.

In some embodiments, the plurality of through holes 31 are symmetrically distributed. Specifically, referring to FIG. 13, the plurality of through holes 31 are symmetrical along a first symmetry axis L. The first symmetry axis L is a straight line passing through the center O of the reflective pattern 30 and parallel to a plane where the reflective pattern 30 is located. The through holes 31 on both sides of the first symmetry axis L are symmetrically distributed. There is at least one through hole 31 corresponding to each side of the light-emitting device 20. The light emitted by the light-emitting device 20 is emitted from the through holes 31 on both sides. Since the through holes 31 are symmetrically distributed, the amount of light emitted from the through holes 31 on both sides is approximately the same. The light is evenly emitted from both sides of the light-emitting device 20, thereby improving the brightness uniformity of the corresponding region of the reflective pattern 30. The higher the degree of symmetry, the better the light uniformity will be.

In some embodiments, continuing to refer to FIG. 12, a distance between the through hole 31 and the edge of the reflective pattern 30 is a first distance d1, and the first distance d1 is at least 0.1 mm, such as 0.1 mm, 0.15 mm, or 0.2 mm, and the through hole 31 should be as proximate to the edge of the reflective pattern 30 as possible. The light-emitting device 20 illuminates the edge of the reflective pattern 30 with a gradually decreasing amount of light, so that the brightness of the dark region D at the edge of the reflective pattern 30 is minimized, and therefore, by providing through hole(s) 31 at the edge of the reflective pattern 30, the light-emitting device 20 can emit light from the through hole(s) 31 proximate to the edge of the reflective pattern 30, and thereby reduce the extent of the dark region D at the edge of the reflective pattern 30.

In some embodiments, continuing to refer to FIG. 12, a distance between a through hole 31 closest to the center O of the reflective pattern 30 and the center O of the reflective pattern 30 is a second distance d2, and the second distance d2 is at least 0.75 mm, such as 0.75 mm, 0.9 mm, 0.95 mm, or 1 mm. If this through hole 31 is too proximate to the center O of the reflective pattern 30, the light emitted by the light-emitting device 20 from the through hole 31 proximate to the center O of the reflective pattern 30 is high in amount and high in brightness, resulting in a region proximate to the center O of the reflective pattern 30 having a higher brightness than the other regions in the same reflective pattern 30, which results in a poor uniformity of the brightness of the reflective pattern 30. Therefore, in order to solve the above problem, the second distance d2 cannot be too small.

In some embodiments, continuing to refer to FIG. 12, the shape of the projection of the through hole 31 on the substrate 10 is circular. That is, the through hole 31 is in the shape of a cylinder, an inner wall of the cylinder is rounded and smooth, and the light incident to the inner wall of the through hole 31 can be repeatedly reflected on the inner wall of the cylinder and then ejected, with less light loss. In this case, the size of the through hole 31 is the diameter of the through hole 31, and the diameter of the through hole 31 ranges from 0.1 mm to 0.2 mm, such as 0.1 mm, 0.13 mm, 0.15 mm, 0.18 mm, or 0.2 mm. In some embodiments, the shape of the projection of the through hole 31 on the substrate 10 may be a polygon, such as a rectangle, a square, a pentagon, or a hexagon. In this case, the size of the through hole 31 is the maximum distance of a diagonal line of the through hole 31, where the diagonal line refers to a diagonal line of the shape of the orthographic projection of the through hole 31. The size of the through hole 31 ranges from 0.1 mm to 0.2 mm, such as 0.1 mm, 0.13 mm, 0.15 mm, 0.18 mm, or 0.2 mm. If the diameter of the through hole 31 is too small, it is not conducive to printing. If the diameter of the through hole 31 is too small, it is not conducive to printing; and if the diameter of the through hole 31 is too large, the reflection effect of the reflective pattern 30 is weakened, making the range of the dark region D in the gap region of the reflective patterns 30 expand, which is not conducive to realizing the brightness uniformity of the light-emitting module 100.

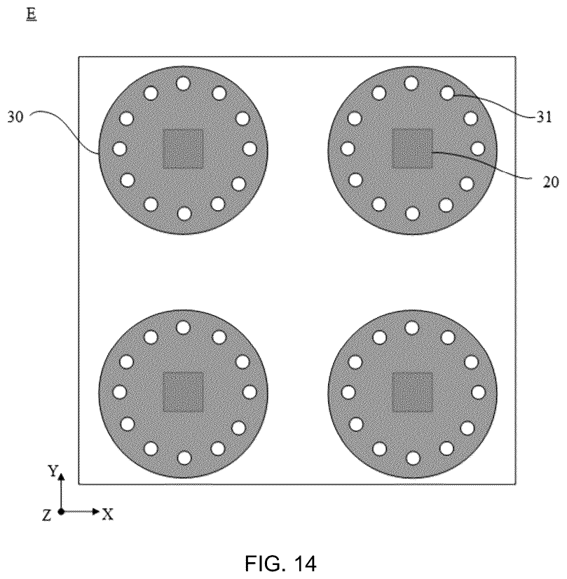

FIG. 14 is a partially enlarged view of a light-emitting module corresponding to the E region of FIG. 8.

In some embodiments, referring to FIG. 14, the reflective pattern 30 may be in a shape of a circle. The center O of the reflective pattern 30 is the center of the circle, and the emission region may be an annulus with the center O of the reflective pattern 30 as the same center of the circle. In this way, the distances from the through holes 31 in the same emission region to the center of the circle can be set to be equal, which is convenient for manufacturing.

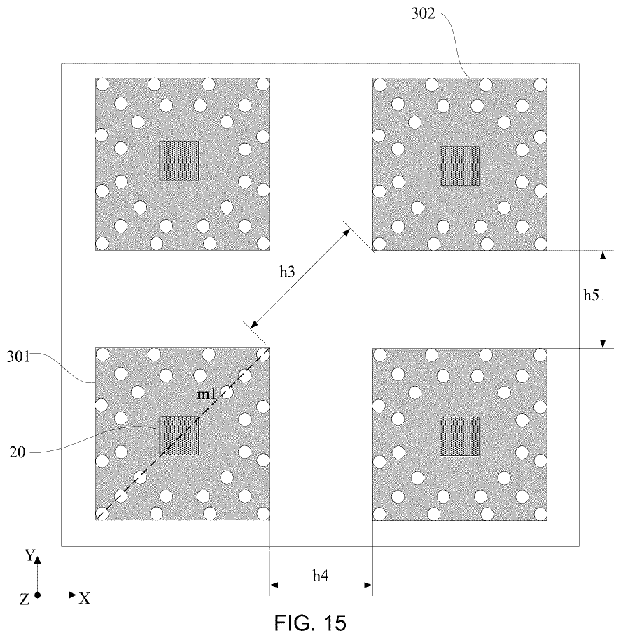

FIG. 15 is a structural diagram of still yet another reflective pattern provided by embodiments of the present disclosure.

In some embodiments, referring to FIG. 15, the reflective pattern 30 is in the shape of a polygon, such as a quadrilateral (rectangle or square), a pentagon, or a hexagon.

In some embodiments, continuing to refer to FIG. 15, the plurality of reflective patterns 30 are arranged in an array, and the plurality of reflective patterns 30 include first reflective patterns 301 and second reflective patterns 302. Along a direction of a diagonal line (a first diagonal line m1) of the first reflective pattern 301, the first reflective patterns 301 and the second reflective patterns 302 are arranged in sequence, where the diagonal line refers to a diagonal line of the shape of an orthographic projection of the first reflective pattern 301 on the substrate 10. A direction in which multiple reflective patterns 30 are arranged in the same row is a horizontal direction, and a direction in which multiple reflective patterns 30 are arranged in the same column is a vertical direction.

In a first reflective pattern 301, the number of through holes 31 in the direction of the first diagonal line m1 is greater than the number of through holes 31 in the horizontal direction or the vertical direction; and/or, in a second reflective pattern 301, the number of through holes 31 in the direction of the first diagonal line m1 is greater than the number of through holes 31 in the horizontal direction or the vertical direction. For example, in the first reflective pattern 301, the number of through holes 31 in the direction of the first diagonal line m1 is greater than the number of through holes 31 in the horizontal direction or the vertical direction; as another example, in the second reflective pattern 301, the number of through holes 31 in the direction of the first diagonal line m1 is greater than the number of through holes 31 in the horizontal direction or the vertical direction; as yet another example, in the first reflective pattern 301, the number of through holes 31 in the direction of the first diagonal line m1 is greater than the number of through holes 31 in the horizontal direction or the vertical direction, and in the second reflective pattern 301, the number of through holes 31 in the direction of the first diagonal line m1 is greater than the number of through holes 31 in the horizontal direction or the vertical direction.

A third distance h3 between a first reflective pattern 301 and a second reflective pattern 302 in the direction the first diagonal line m1 is greater than a fourth distance h4 between the first reflective pattern 301 and the second reflective pattern 302 in the horizontal direction, and greater than a fifth distance h5 between the first reflective pattern 301 and the second reflective pattern 302 in the vertical direction. Therefore, in a case where the number of the through holes 31 provided in the reflective pattern 30 makes a region within a range of the fourth distance h4 and the fifth distance h5 become a bright region L, a portion of a region within a range of the third distance h3 is not illuminated by the light emitted from the through holes 31 and remains a dark region D. In order to increase the amount of light emitted in the direction of the first diagonal line m1, the number of through holes 31 in this direction is increased, so that the light emitted by the light-emitting device 20 is emitted more from the direction of the first diagonal line m1, thereby reducing the range of the dark region D in the region where the third distance h3 is located, so as to improve the brightness uniformity of the light-emitting module 100 and thereby improve the display effect of the display apparatus.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A light-emitting module, comprising:
a substrate;
a plurality of light-emitting devices, the light-emitting devices being disposed on the substrate; and
a plurality of reflective patterns, disposed on a side of the light-emitting devices away from the substrate, wherein adjacent reflective patterns in the plurality of reflective patterns are provided with a gap therebetween; the reflective patterns are in one-to-one correspondence with the light-emitting devices, and an orthographic projection of a light-emitting device in the plurality of reflective patterns on the substrate is located within an orthographic projection of a reflective pattern in the plurality of reflective patterns on the substrate; and the reflective pattern is provided with at least one through hole, and an orthographic projection of the at least one through hole on the substrate is non-overlapping with the orthographic projection of the light-emitting device on the substrate.

2. The light-emitting module according to claim 1, wherein the reflective pattern is provided with a plurality of through holes, and in the plurality of through holes, a number of through holes proximate to a center of the reflective pattern is less than a number of through holes away from the center of the reflective pattern.

3. The light-emitting module according to claim 1, wherein the reflective pattern is provided with a plurality of through holes of a same size.

4. The light-emitting module according to claim 1, wherein the reflective pattern is provided with a plurality of through holes, and in the plurality of through holes, a size of a through hole proximate to a center of the reflective pattern is less than a size of a through hole away from the center of the reflective pattern.

5. The light-emitting module according to claim 1, wherein the reflective pattern is provided with a plurality of through holes in multiple emission regions, through holes in each emission region having a same distance from a center of the reflective pattern, and the plurality of through holes are arranged in a circular array.

6. The light-emitting module according to claim 5, wherein the plurality of through holes are arranged in a staggered manner.

7. The light-emitting module according to claim 5, wherein a shape of the orthographic projection reflective pattern is a circle, and along any radial direction of the reflective pattern, multiple through holes in the plurality of through boles are arranged in sequence.

8. The light-emitting module according to claim 1, wherein the plurality of through holes are symmetrically distributed.

9. The light-emitting module according to claim 1, wherein a shape of the orthographic projection of the at least one through hole on the substrate is a circle or a polygon, and a size of the at least one through hole ranges from 0.1 mm to 0.2 mm.

10. The light-emitting module according to claim 1, wherein a minimum distance between the at least one through hole and an edge of the reflective pattern is 0.1 mm.

11. The light-emitting module according to claim 1, wherein a minimum distance between a through hole in the at least one through hole that is closest to a center of the reflective pattern and the center of the reflective pattern is 0.75 mm.

12. The light-emitting module according to claim 1, wherein a shape of the reflective pattern is a circle or a polygon.

13. The light-emitting module according to claim 1, wherein
the plurality of reflective patterns are arranged in an array, the plurality of reflective patterns include first reflective patterns and second reflective patterns, and along a direction of diagonal lines of the first reflective patterns, the first reflective patterns and the second reflective patterns are arranged in sequence, wherein
a first reflective pattern in the first patterns is provided with a plurality of through holes, and in the plurality of through holes, a number of through holes in a direction of a diagonal line of the first reflective pattern is greater than a number of through holes in a horizontal direction or a vertical direction; and/or
a second reflective pattern in the second reflective patterns is provided with a plurality of through holes, and in the plurality of through holes, a number of through holes in the direction of a diagonal line of the first reflective pattern is greater than a number of through holes in the horizontal direction or the vertical direction.

14. The light-emitting module according to claim 1, wherein a thickness of the reflective pattern ranges from 25 μm to 50 μm.

15. The light-emitting module according to claim 1, wherein a distance between a side of the reflective pattern proximate to the substrate and the light-emitting device ranges from 20 μm to 50 μm.

16. The light-emitting module according to claim 1, further comprising:
a bottom reflective layer, disposed on a side of the substrate proximate to the plurality of reflective patterns.

17. The light-emitting module according to claim 1, further comprising:
a protective layer, disposed on the plurality of light-emitting devices, wherein the plurality of reflective patterns are disposed on the protective layer.

18. The light-emitting module according to claim 17, wherein a refractive index of the protective layer is greater than a refractive index of the reflective pattern.

19. A display apparatus, comprising the light-emitting module according claim 1.

20. The light-emitting module according to claim 1, wherein a reflectivity of the reflective pattern ranges from 85% to 93%.
